(19) United States
(12) Patent Application Publication
(10) Pub. No.: US 2010/0040979 A1
(43) Pub. Date: Feb. 18, 2010

(54) SYSTEMS AND METHOD FOR FABRICATING SUBSTRATE SURFACES FOR SERS AND APPARATUSES UTILIZING SAME

(76) Inventor: Wayne A. Weimer, Plano, TX (US)

Correspondence Address: DUNLAP CODDING, P.C., PO BOX 16370, OKLAHOMA CITY, OK, 73113, US

(21) Appl. No.: 12/579,060

(22) Filed: Oct. 14, 2009

Related U.S. Application Data
(63) Continuation of application No. 11/146,866, filed on Jun. 7, 2005, now abandoned.

(51) Int. Cl. C23C 16/52; B05D 5/12; C23C 14/34; B29C 35/08; G03F 7/00

(52) U.S. Cl. 430/296; 427/123; 427/125; 427/8; 204/192.13; 264/400

(57) ABSTRACT

The present invention is related in general to chemical and biological detection and identification and more particularly to systems and methods for the rapid detection and identification of low concentrations of chemicals and biomaterials using surface enhanced Raman spectroscopy.

### CROSS-REFERENCE TO RELATED APPLICATIONS

This application is a continuation of U.S. Ser. No. 11/146,866 filed Jun. 7, 2005 and claims priority under 37 C.F.R. §1.19(e) to provisional application Ser. No. 60/557,753 filed Jun. 7, 2004, entitled “SYSTEM AND METHOD FOR FABRICATING SUBSTRATE SURFACES FOR SURFACE ENHANCED RAMAN SPECTROSCOPY”, the entire contents of which are hereby expressly incorporated herein by reference in their entirety as if set forth explicitly herein.

### BACKGROUND OF THE INVENTION

1. Field of the Invention

The present invention is related in general to chemical and biological detection and identification and, more particularly, to systems and methods for the rapid detection and identification of low concentrations of chemicals and biomaterials using surface enhanced Raman spectroscopy.

2. Description of the Related Art

Poorly performing substrates have plagued Surface Enhanced Raman Spectroscopy (SERS) as an analytical technique since its discovery in 1977 and have effectively prevented its acceptance by the scientific community as a reliable method for chemical analysis. Despite the discovery of single molecule sensitivity for SERS in 1997 and the subsequent explosion in interest in SERS, little progress has been made toward the development of useful substrates suitable for commercial manufacturing. One aspect of the innovation embodied in the presently disclosed and claimed inventive concepts is the implementation of a systematic approach to substrate design, complete with theoretical and experimental aspects. This unique approach or method optimizes the substrate production process by quantifying the effect of manufacturing process parameters on the performance of the enhancement factors of the substrates produced. Concurrently, a theoretical approach is applied to analyze how the design of the substrate affects the enhancement mechanism. This process provides the capability to produce substrates tuned to predetermined specifications i.e. specifically desired wavelengths. These substrates are useful in a wide variety of applications ranging from benchtop SERS instruments, to handheld chemical detectors, to inexpensive chemical/biological warfare agent sensors.

Due to the wide ranging applicability of Raman spectroscopy to chemical and biological materials, the system is effective for a wide spectrum of chemical and biological analytes. The detector has an intrinsic sensitivity to potentially detect and identify single spores, molecules, viruses, and bacteria. Thus, an entire range of chemical and biological analytes can be detected with a single instrument.

As a vibrational spectroscopic technique, Raman spectroscopy produces signatures rich in chemical structure information that is useful for identifying analyte molecules. There are impressive examples in the literature of Raman spectra collected from biological materials.[1,2] Naumann has tabulated vibrational assignments of the prominent spectral features typically observed in Raman spectra of biological materials.[1]

Raman spectroscopy is a chemical analysis method in which monochromatic radiation interacts with molecules and is shifted in frequency through a process known as scattering. The frequency shift of the scattered radiation is equal to the vibrational frequency of the bonds between atoms in the molecule. Thus, molecules with many bonds produce scattered radiation of many frequencies. Since the vibrational frequencies of most bonds are known and constant, measuring the spectrum of scattered radiation allows the frequency shifts to be determined and the identification of bonds in the analyte molecules to be deduced. The intensity of the scattered radiation is proportional to the number of molecules irradiated so a Raman spectrum may be used to measure the amount of analyte present and the frequency shifts allow the identification of the analyte. Raman scattering is an extremely inefficient process where only one in 10⁸ incident photons is Raman scattered. To be useful as a sensor, the scattering process must be greatly amplified. As is discussed and claimed hereinafter, the presently disclosed and claimed substrates have greatly amplified scattering and thus enable, for the first time, the use of surface enhanced Raman spectroscopy in a commercially efficient and desirous manner.

Historically, a number of challenges have existed prohibiting the successful development and commercialization of SERS substrates. Useful SERS substrates producing enhancement factors >>10⁷ for a wide range of analyte molecules do not exist and current substrates show large enhancements for an extremely limited range of highly conjugated organic molecules such as dyes. Fabrication methods are typically complex multi-step laboratory processes that are not suitable for scale up to production manufacturing levels. Finally, substrate morphology on the nanoscale is difficult to reproduce and the relationship between substrate nanoscale morphology and SERS enhancement factor is poorly understood.

Surface Enhanced Raman Spectroscopy is a vibrational spectroscopic technique that may offer the ultimate in analytical methodology, namely extraordinarily high sensitivity and simultaneous analyte identification capability. Submonolayer detection of adsorbates using SERS was achieved in the 1980's.[3-5] In 1997, Nie and Emory[6] and Kneipp et. al.[7] independently reported extraordinarily high SERS enhancement factors (˜10¹⁴ for rhodamine 6G) and, for the first time, achieved the detection of single molecules using this technique. Sample preparation in the single molecule experiments involved adding the analyte to a dilute silver colloid solution such that the number of analyte molecules approximated the number of metal particles in the colloidal solution. The silver particles were then transferred to a surface for analysis. Other groups have since successfully utilized this method for sample preparation. [8-10]. Recently, Aroca et. al. [11,12] achieved single molecule detection by surface enhanced resonance Raman spectroscopy (SERRS) on dry silver island films produced by thermal vapor deposition of silver on glass microscope slides. Samples were prepared by applying Langmuir-Blodgett monolayers of fatty acids impregnated with organic dyes onto silver films. The dye concentration in the resulting fatty acid film was at sufficiently low concentrations so that only one dye molecule was present in the probed volume during the measurement.

These extraordinary advancements in sensitivity have produced a high level of interest in SERS worldwide, driven in part to understanding the mechanism underlying the exponential enhancement factors. To date, many of the details regarding the enhancement mechanism remain elusive. Some, however, are known. For example, a condition necessary, though not sufficient, to achieve a significant enhancement in the Raman scattered radiation intensity is an overlap of the incident radiation wavelength, scattered radiation wavelength, and the surface plasmon resonance wavelength (SPRW) of the substrate [13-17]. Most of the work to date involves varying the incident laser wavelength to achieve this condition. It would be highly desirable to be able to “tune” the substrate surface plasmon resonance wavelength. This would allow for the substrate surface plasmon resonance to be matched to the fixed wavelengths of economical and readily available lasers.

The recent scientific advancements in SERS cited above stem from the current widespread interest in metal nanomaterials, which is driven largely by their unique optical properties.[18-27] A large number of potential applications exist for nano-optical materials including ultrafast optical switches, optical tweezers, labels for biomolecules, optical filters, biosensors, surface enhanced spectroscopies, plasmonics, and chemical sensors.[28-30] Many of these applications require the nanoparticles to be in metal island film form supported on a substrate. These applications exploit the size-dependent optical properties of nanoparticles. For example, optical absorption and scattering by metal nanoparticles result from the collective oscillation of surface electrons, known as surface plasmons, which are excited by incident electromagnetic radiation. For noble metal particles in the 10 nm to 100 nm dimension range, surface plasmon resonance occurs at wavelengths in the visible and near infrared regions of the electromagnetic spectrum. Greatly enhanced optical absorption and scattering occurs at these surface plasmon resonance wavelengths. The result of the extreme sensitivity of these optical properties on the metal nanoparticle geometry and environment form the basis for the applications listed above.

In order for SERS substrates or any of the other commercial applications for metal nanoparticle materials to be realized, economical fabrication processes must be developed and evaluated. A large number of laboratory methods for the preparation of metal nanoparticle films have been developed including vapor deposition,[31-34] electrochemistry,[35] laser ablation,[36,37] citric reduction,[38] wet chemical synthesis,[39-40] gold cluster formation,[41] self-assembly of nanoparticle arrays,[42-45] electron beam lithography,[17] STM assisted nanostructure formation,[46-48] and nanosphere lithography.[49-53]

Unfortunately, none of the methods for fabricating SERS substrates mentioned above have been developed into a process for large scale manufacture. Of the wide array of techniques available for the mass production of nanoscale metal particles, thermal evaporation is one of the oldest and most inexpensive methods known. Also, the equipment involved in thermal evaporation is commonly available in most materials research and production facilities.[54] However, concerns have existed about the capability of this method for precise deposition process control and the reproducibility of deposited material properties.[55] The present invention overcomes these barriers.

An enormous body of literature exists describing a wide variety of SERS substrate materials and designs. Numerous nanoscale structures have been evaluated for SERS activity including gratings, colloidal particles on surfaces, and colloidal particles embedded in polymers and transparent inorganic materials. Most are SERS active, but have not achieved enhancement factors greater than 10⁵, nor a high degree of control over SPRW tunability. There exists an equally large body of literature regarding the theory of SERS. Despite this, a generally applicable model, proven by experiment, has yet to emerge. The status of SERS has been documented in several reviews.[56-60] Here, the more promising designs are highlighted.

Natan developed several clever methods, including self assembly, to manipulate gold and silver colloidal particles on surfaces to affect control of the surface plasmon resonance wavelengths. [61-64] This work resulted in a marked improvement in the reproducibility of the SERS spectra collected from these substrates. Natan also demonstrated the use of SERS for the detection of biomolecules by developing a gold/Cytochrome-C conjugate for use in a colloidal silver sol.[65,66] Mirkin reported the use of gold nanoparticles attached to organic dyes for use as SERS markers for DNA. [67] Van Duyne has developed an elegant method for producing tunable silver film substrates called nanosphere lithography, in which a monolayer of close-packed spheres is used as a vapor deposition mask. Since metal is deposited only beneath the open spaces between the spheres, precise control of island geometry, and thus surface plasmon resonance wavelength, is achieved.[28,68,69] Noteworthy advancements have also been reported by several other groups on the ability to adjust or tune the surface plasmon resonance wavelength of metal films.[17,34,45,70-74]

Progress toward the development of SERS as an analytical technique has also been reported recently. Smith has developed analytical applications for surface enhanced resonance Raman spectroscopy (SERRS), detected DNA at extremely low concentrations,[75] developed dyes specifically for SERRS,[76] and demonstrated the analytical utility of silver colloids for SERRS.[77-79] Viets and Hill have shown that the laser power at the surface of silver island films must be <4.5 kW/cm² to maintain both SERS enhancement and a linear relationship between the SERS signal and laser power.[80] The signal enhancement effect in SERS has been shown to decrease to 50% of its value at the metal surface at a distance of between 7 Å and 25 Å, [81-84] bringing into question the viability of functionalizing SERS surfaces with large molecules.

A very common problem with SERS is carbon contamination of silver.[85-88] The actual source of carbon, such as vacuum pump oil backstreaming, spontaneous decomposition of atmospheric organics, photodegradation of organics during SERS measurement, or source metal contamination, is not entirely clear since silver substrates are prepared using a variety of methods. Silver is the most commonly used metal for SERS substrates since it thought to provide the highest enhancement. The SERS signal for carbon is strongly enhanced by silver. In fact, the enhanced signal of carbon has been used to demonstrate high sensitivity SERS measurements.[34,89] However, the presence of large carbon features in SERS spectra creates enormous (possibly insurmountable) difficulties in establishing a reliable spectral baseline. The lack of a stable baseline severely limits the utility of SERS for quantitative measurements. The strength and variability of this carbon feature precludes the quantitation of any analyte at low concentrations. This problem is probably ubiquitous and will likely limit the applicability of SERS where quantitative ultrasensitivity is required. Considering that single molecule detection of R6G had been achieved on gold particles, [90] gold may be preferable over silver for SERS substrates generally. Frequently, recognizable carbon features in published SERS spectra are observed. Several SERS spectral interpretations have been questioned recently because of possible carbon features in the spectra. [88]

SERS enhancement factors are determined by comparing the measured SERS signal intensity to the measured intensity of a fluorescent molecule of known fluorescence cross section such as Rhodamine 6G (R6G) excited at 514.5 nm and applying Equation 1. In this embodiment of the present invention, the SERS and fluorescence measurements are made under identical experimental conditions except that the fluorescence measurements are performed on a nonenhancing substrate. Thus, the enhancement factor E_{f} is defined as:

$${E}_{f} = \frac{{σ}_{F}}{{σ}_{R}} k \frac{{I}_{ER}}{{I}_{F}} = {10}^{14} k \frac{{I}_{ER}}{{I}_{F}} \qquad ( 1 )$$

where σ_{F} is the R6G fluorescence cross section (σ_{F}=10⁻¹⁶ cm²),[91] σ_{R} is the analyte unenhanced Raman cross section (σ_{R}=10⁻³⁰ cm²),[6,91] I_{ER} is the measured analyte SERS intensity in cps, I_{F} is the intensity of R6G fluorescence using 514.5 nm excitation in cps, and k is a factor to correct for instrumental spectral response and excitation laser intensity between the Raman and fluorescence measurements. Thus, the SERS cross section can be unambiguously calculated in a straightforward fashion and is traceable to the accurately known cross section of a fluorescent molecule. Other fluorophores may be substituted for R6G and used in Equation 1, provided that their fluorescence cross sections are known at sufficient accuracy.

### SUMMARY OF INVENTION

The present invention exploits the fact that the intensity of the Raman spectrum produced by molecules and/or biomaterials in contact with a roughened metal surface can be enhanced by many orders of magnitude compared to the intensity of the Raman spectrum produced by the same molecules in the absence of the roughened metal. This method is known as Surface Enhanced Raman Spectroscopy (“SERS”). The present invention is a method and system for economically producing SERS surfaces that enhance the intensity of Raman spectra by greater than 10 orders of magnitude. In addition to the high enhancement of the Raman spectra, the surfaces described herein exhibit reproducible enhancements for a wide range of analyte molecules and biomaterials.

The present invention is directed to a system and method that analyzes molecules utilizing surface enhanced Raman spectroscopy. In embodiments of the present invention, substrates are utilized that are preferably fabricated to produce an optimum level of Raman signal that is sufficient for detection of low concentrations of chemicals and biomaterials and simultaneously sufficient for unambiguously identifying same. Embodiments of the present invention further make use of on demand inkjet droplet dispensers to optimally place known amounts of liquid analyte solutions onto the substrate surface for detection by surface enhanced Raman spectroscopy. Precise control of the droplet placement onto the substrate allows for the efficient solvent evaporation and physisorption of the analytes onto the surface resulting in the generation of extremely large enhancements in the Raman signal. Embodiments of the present invention further make use of a spectral database and software algorithms for the purpose of comparing measured spectra to spectra contained in the database for identification and quantitative determination of the analyte concentration.

Embodiments of the present invention may advantageously control the nanoscale morphology of the substrates for optimal detection and identification of chemical and biological substances. Precise control of the nanoscale morphology allows molecular specificity to be incorporated into the substrate, allowing detection of chemical and biological substances in the presence of background substances and clutter. For example specific biological analytes may be detected in body fluids without a predetection separation process. Embodiments of the present invention enable such control of the substrate's ability to enhance the Raman signal reproducibly by use of a perimeter shadow mask and controlling a deposition process (e.g., a thermal evaporation process, sputter deposition, or chemical vapor deposition) utilized to create the substrate. For instance, a particular deposition process reduces to an acceptable level or eliminates deleterious edge effects (inhomogeneous films caused by exposed substrate edges during deposition) by use of an optimally designed perimeter shadow mask. Thus, various sample substrates may be obtained with each substrate produced optimized for a specific analyte or group of analytes according to the respective deposition parameter value(s). The sample substrate that produces the largest surface-enhanced Raman spectroscopy enhancement may be utilized as the selected substrate for a suitable detection system. The sample substrate that produces the largest surface-enhanced Raman spectroscopy enhancement may be determined utilizing either empirical or computational methods.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiments disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawing, in which:

FIG. 1 depicts measured Raman spectra demonstrating single spore/virus signal enhancement for pollen (Live Oak), Bacillus thuringiensis, Bacillus cereus, Bacillus subtilis, and human enteric coronavirus.

FIG. 2 depicts SERS spectra of live and heat killed Bacillus thuringiensis spores. Spore samples were heated to temperatures listed for 8 minutes. The Raman spectral peak heights decrease with increasing temperature. At 300° C., the spores were denatured as shown by the carbon dominated Raman spectrum.

FIG. 3 depicts SERS spectra of whole urine and whole blood samples.

FIG. 4 depicts SERS spectra of Rhodamine 6G collected at various positions showing the extremely high enhancement and reproducibility of the SERS substrate.

FIG. 5 depicts SERS spectra derived by exposing a SERS substrate to the saturated vapor of trinitrotoluene (TNT) for various times.

FIG. 6A shows extinction spectra for gold films listed in Table A. FIG. 6B shows extinction spectra for films 1, 2, and 15 listed in Table A.

FIG. 7 depicts a cross sectional view of one embodiment of an optimized perimeter shadow mask.

FIG. 8 depicts a photograph illustrating non-uniform film properties due to edge effects.

FIG. 9 depicts a SERS based detection concept schematic.

FIG. 10 depicts a liquid sample dispensing for SERS measurement.

FIG. 11 depicts a block diagram of sensor component subsystems.

FIG. 12 depicts a timing diagram for proposed chemical and biological agent detection system where the complete detection cycle time is 1 minute.

FIG. 13 depicts the calculated surface enhanced Raman signal for (a) toxin and (b) spore airborne concentrations at various SERS enhancement factors where the vertical dotted lines show realistic limit of detection (LOD) requirements and the stepwise curve in (b) reflects detection of 1, 2, and 3 spores.

FIG. 14 depicts the calculated probability of error.

### DETAILED DESCRIPTION OF THE INVENTION

Before explaining at least one embodiment of the invention in detail, it is to be understood that the invention is not limited in its application to the details of construction and the arrangement of the components set forth in the following description or illustrated in the drawings. The invention is capable of other embodiments or of being practiced or carried out in various ways. Also, it is to be understood that the phraseology and terminology employed herein is for purpose of description and should not be regarded as limiting.

The present invention is useful for many chemical or biological detection and sensor applications that require rapid detection. The present invention is a chemical and biological detection platform based upon surface enhanced Raman spectroscopy (SERS), a molecular detection technique that has been made ultrasensitive. The technological breakthrough that has enabled the realization of SERS as an ultrasensitive chemical and biological detection method for the presently disclosed and claimed applications has been the development of SERS substrates exhibiting extremely high enhancement-factors as described herein. The system incorporates SERS substrates that amplify the Raman signal by at least 8 orders of magnitude and, in some instances, 11 orders of magnitude. These substrates allow the system to produce vibrational spectra of analytes, enabling detection and identification at the single spore or attogram (10⁻¹⁸ g) level for toxins and chemical agents.

The fabrication methodology of the presently disclosed and claimed invention yields SERS substrates that produce highly reproducible spectra both at various positions on a single substrate and for same samples on different identically prepared substrates. By controlling the morphology of the substrates on the nanoscale level, molecular specificity can be incorporated into the system, allowing for the selective amplification of targeted analytes. Controllable molecular specificity allows the detection of and identification of target chemical and biological agents in the presence of high concentrations of interferents and background clutter. Since the enhancement of the signal is so great, use of relatively inexpensive low performance optical components in the system is feasible, making the system affordable.

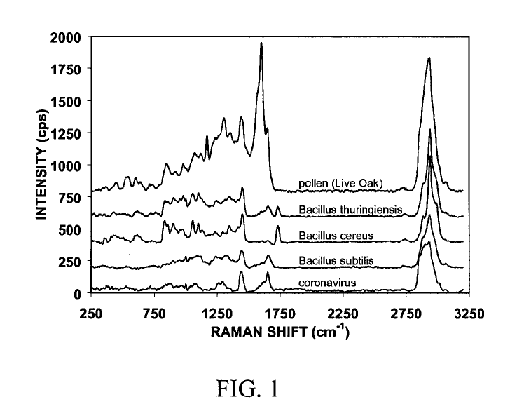

The performance of the present invention for biological warfare agent stimulant samples is shown in FIG. 1. For comparison, spectra collected from Live Oak pollen single spore, Bacillus thuringiensis single spore, Bacillus cereus single spore, Bacillus subtilis single spore, and a single human enteric coronavirus[92] are shown. The samples were suspended in water and drop cast onto the substrates prior to analysis. The spectra were digitally filtered and the fluorescent background was subtracted. The spectra show the high level of information contained in Raman spectra of biological materials that is essential for differentiation and identification. Peak heights of up to 1000 cps were achieved and signals were integrated for 100 seconds. A low incident laser power of 2.5 mW at 632.8 nm was used. The spectral signal to noise ratio (SNR) values range from 10 in the “fingerprint” region (800-1750 cm⁻¹) to over 39 at the major peaks.

Since the spectral features in the spectra in FIG. 1 are broad, a low spectral resolution, high optical throughput miniature spectrometer can be used to collect the SERS spectra. An examination of the spectral region of 1500 to 1750 cm⁻¹ shows that this region is unique to all 5 spectra. Although the peaks in this region for Bacillus subtilis and the coronavirus are quite similar, the peak shapes at 2800 to 3100 cm⁻¹ are quite different. Thus, the overall shape of the spectrum will be used to identify the presence of bacteria in the sample and features unique to individual species can be used to identify a particular chemical or biological agent. For example, a robust pattern recognition processing algorithm incorporating Ward's algorithm for cluster analysis[2] can easily deconvolute the traces shown in FIG. 1, compare the deconvoluted spectra to a spectral library database, and identify bacteria present in the sample. Cluster analysis of vibrational spectra has not only been shown to be capable of differentiating between different bacteria in samples, but has also been shown to be capable of differentiating between individual strains of a single bacteria. This capability is described in detail below.

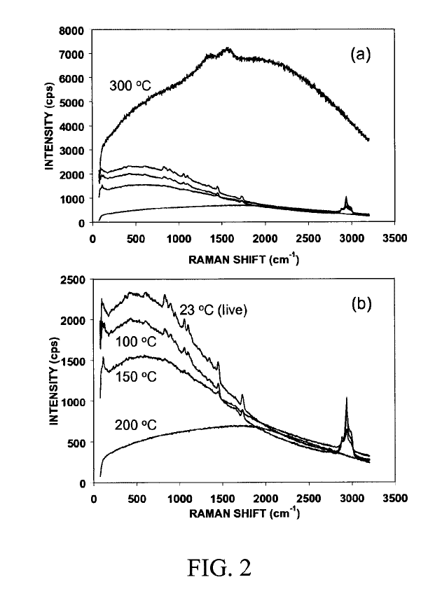

A serious and current limitation of many biological agent detection systems is the inability to discriminate between live and dead biomaterials. Encouraging SERS results regarding this limitation are shown in FIG. 2. Spectra were collected on live Bacillus thuringiensis spore samples following heating to 100° C., 150° C., 200° C., and 300° C. The spectra show that compared to the live spore spectrum, both the fluorescent and Raman signals decreases upon heating to 100° C. Additional heating to 150° C. further reduces the fluorescence and Raman intensity. Heating to 200° C. decreases the fluorescence further and the Raman spectrum is no longer observed. Finally, heating to 300° C. decomposes the biomaterial and a spectrum characteristic of carbon is observed.

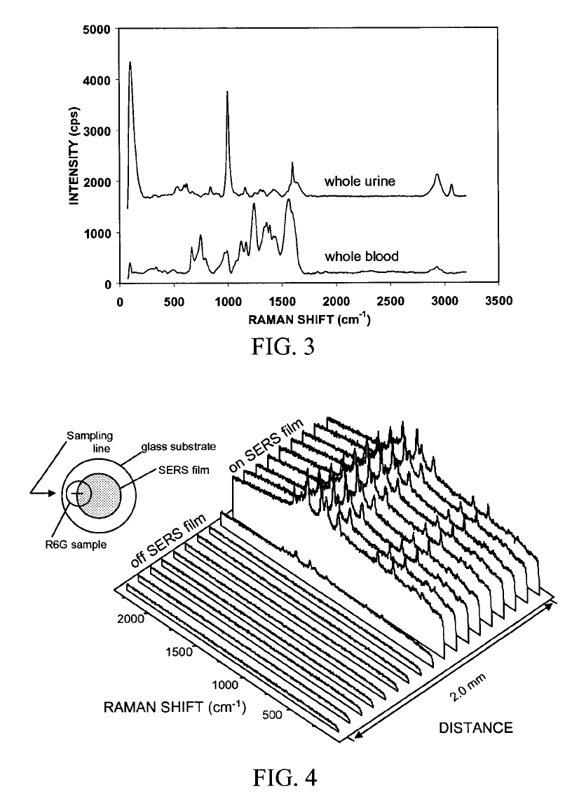

In FIG. 3, the versatility of the presently disclosed and claimed invention is shown by producing strong spectra for highly complex biological samples, whole urine and whole blood. These spectra were collected similarly to those in FIG. 1, integrating over 40 seconds. No sample preparation was performed on these materials except for drop casting them onto the substrates. The samples were allowed to dry at room temperature. These samples demonstrate that for even highly complex mixtures of biological samples, a large amount of spectral information may be obtained to allow the post measurement processing algorithms to effectively extract out component spectra. These component spectra can then be used to quantify and identify numerous materials in the sample mixture.

A major advance in performance achieved with the present invention is reproducibility in both enhancement factor and sample application to the substrate. In FIG. 4, SERS spectra are shown demonstrating this reproducibility. The spectra were collected from a drop cast sample of 1.0×10⁻⁶ molar R6G where half of the sample was on the SERS surface and half was not, as illustrated in FIG. 4. Spectra were collected at equally spaced positions as the R6G was sampled over a 2.0 mm distance (see sample line in FIG. 4) from a region where the sample was not on the SERS surface, to a region where the sample was on the SERS surface. Clearly, spectra collected off the SERS surface show no Raman features whereas the spectra collected on the SERS surface are highly enhanced and exhibit excellent constancy in intensity, i.e. reproducibility. Each spectrum was collected using only 2.5 mW of incident laser power at 632.8 nm and was integrated for only 1 second. In addition to this demonstration of reproducibility at different positions on a single substrate, similar levels of reproducibility have also been demonstrated on different substrates.

The substrates resulting from the present invention are not only fabricated by an inexpensive process that is scaleable to high volume production levels, but their performance demonstrates unprecedented levels of signal reproducibility and high SERS enhancement. The data in FIGS. 1-4 show the wide versatility of the present invention to reproducibly amplify the Raman signal of a diverse range of analytes, both biological and chemical.

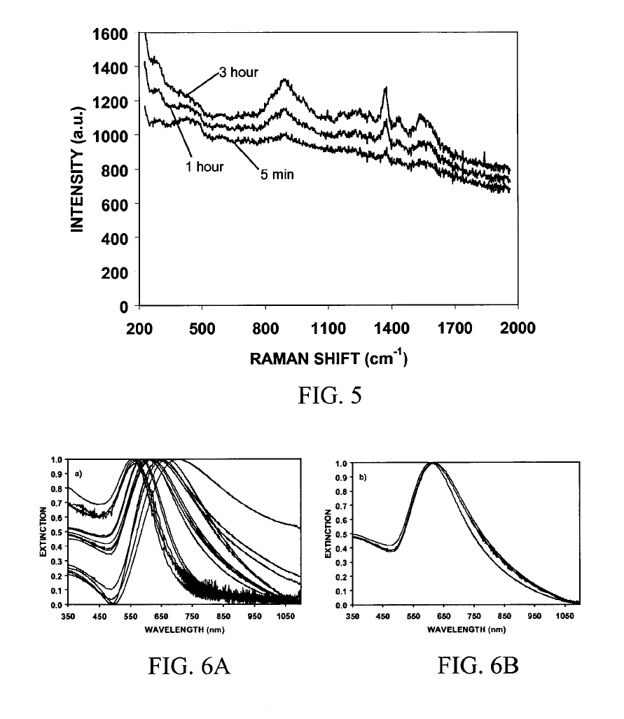

The extreme sensitivity of the present invention is depicted in FIG. 5, where SERS spectra are shown from substrates exposed to the vapor of trinitrotoluene (TNT), a common explosive material. A 2 ml vial with cap removed containing a 10 microgram piece of TNT was placed in a polycarbonate 4 inch by 4 inch petri dish together with a SERS substrate. The SERS substrate consisted of a SERS film deposited onto the surface of a standard glass microscope slide. The petri dish was closed, allowing the TNT to saturate the enclosed air inside the petri dish. The spectra in FIG. 5 show that measurable SERS signals were obtained for exposures to the TNT vapor in 1 hour and larger signals were obtained in 3 hours. The only source of TNT available to the SERS substrate was exposure to the TNT vapor released from the TNT piece. It is noteworthy that a small SERS signal was observed in 5 minutes by merely handling a SERS substrate in the vicinity of the work area near the open vial of TNT. These spectra show the potential of the SERS substrates in an explosive vapor sensor application.

### SERS Substrate Production

The fabrication of SERS substrates in one embodiment of the presently disclosed and claimed invention involves preparing a underlying substrate material, performing the deposition, possibly performing a post deposition treatment, and verifying the substrate performance. The single most important parameter of performance for SERS substrates is reproducibility of high signal amplification both at all points on the surface and on different substrates prepared similarly.

SERS Substrate Design

Initially, a material must be chosen on which to deposit the SERS amplifying surface. The role of the substrate material is primarily to provide a support for the film, although the optical properties of the material will affect so some extent the recipe for optimizing the amplifying SERS film.

A design of experiments (DOE) is then constructed and executed to define the deposition parameter space and quantify the effect of each parameter on the SERS amplification and reproducibility of the film. Experimental designs are statistically robust methods for quantifying the effects of process parameters on a product with the minimum number of experimental runs. [93] Deposition parameters such as mask design, substrate temperature, deposition rate, SERS film thickness, post deposition annealing time and temperature, etc. can be included in the film deposition parameters to be optimized in the DOE. Optimization of the deposition parameters for a given analyte is achieved by performing SERS measurements on identically prepared samples applied to each of the SERS films produced in the DOE.

Thus, an effective approach to evaluating thermal evaporation for producing SERS tunable films is to perform a DOE whereby a specific number of depositions are performed at prescribed parameter value combinations to yield the most information about the process with the minimum number of experimental runs. This approach is commonly used in the industry to efficiently evaluate the effect of control parameters on a process. As a result of this optimization effort, the thermal evaporation process is capable of producing metal island films whereby the SERS of the film could be tuned throughout the visible and into the near infrared regions of the electromagnetic spectrum. For example, films can be produced with surface plasmon resonance wavelengths within ±1 nm of design desired wavelengths.

As an example of the DOE process, we used a 3-factor Box-Behnken DOE as a thermal evaporator that prescribed 15 depositions at specific parameter setting combinations (see e.g. R. Gupta, M. J. Dyer, and W. A. Weimer, J. Appl. Phys., 92, 5264 (2002)). The three DOE factors (or deposition parameters) we chose to evaluate were substrate temperature (Tₛ), deposition rate (R_{d}), and film thickness (T_{f}) and their ranges were 31-120° C., 0.3-1.2 Å/s, and 10-30 Å respectively. The DOE called for 3 of the runs to be replicate runs with parameters set at their mid points, Tₛ=75.5° C., R_{d}=0.75 Å/s, and T_{f}=30 ↑. The exact sequence of 15 depositions to produce the gold films prescribed by the DOE is shown in Table A. Each film was deposited over a 11.4 mm diameter on 18.0 mm diameter 0.15 mm thick circular borosilicate glass cover slips (from Fisher Scientific). Also shown in Table A are measured SPRW values for each film derived from extinction spectra shown in FIG. 6A. For each spectrum an SPRW value was assigned to the wavelength corresponding to the extinction maximum. The calculated SPRW values in Table A were obtained from an empirical equation generated from the DOE statistical analysis as described herein below.

TABLE A
Gold Film Deposition Matrix.

| | | Depo- | Film | SPRW | | |
|---|---|---|---|---|---|---|
| | Substrate | sition | Thick- | Calcu- | SPRW | |
| Sam- | Temperature | Rate | ness | lated | Measured | Difference |
| ple | (° C.) | (Å/s) | (Å) | (nm) | (nm) | (nm) |
| 1 | 75.5 | 0.75 | 30 | 615 | 616 | −0.59 |
| 2 | 75.5 | 0.75 | 30 | 615 | 620 | −4.59 |
| 3 | 75.5 | 1.2 | 10 | 563 | 569 | −5.87 |
| 4 | 75.5 | 1.2 | 50 | 650 | 650 | −0.15 |
| 5 | 31 | 0.75 | 50 | 710 | 707 | 2.60 |
| 6 | 120 | 0.3 | 30 | 588 | 586 | 2.08 |
| 7 | 31 | 0.75 | 10 | 582 | 574 | 7.88 |
| 8 | 75.5 | 0.3 | 10 | 564 | 564 | 0.38 |
| 9 | 120 | 0.75 | 50 | 599 | 607 | −7.65 |
| 10 | 31 | 1.2 | 30 | 656 | 658 | −1.92 |
| 11 | 31 | 0.3 | 30 | 666 | 674 | −8.17 |
| 12 | 75.5 | 0.3 | 50 | 650 | 644 | 6.10 |
| 13 | 120 | 0.75 | 10 | 555 | 557 | −2.37 |
| 14 | 120 | 1.2 | 30 | 596 | 588 | 8.33 |
| 15 | 75.5 | 0.75 | 30 | 615 | 610 | 5.41 |

The tunability in extinction maxima and corresponding SPRW values is clearly illustrated in the spectra shown in FIG. 6A. An examination of the extinction spectra in FIG. 6B indicates that the useful range of tunability for these films is limited to values greater than 475 nm. Below this limit, absorption due to d electron transitions dominates the optical properties of gold. FIG. 6B shows that nearly identical spectra were obtained from the three identical runs producing films 1, 2, and 15 in Table A. The reproducibility of the process in FIG. 6B is excellent.

λ_{sprw}=575-0.839Tₛ−43.32R_{d}+5.68T_{f}+0.00396Tₛ²+0.225TₛR_{d}−0.0233TₛT_{f}+16.5R_{d}²+0.0278R_{d}T_{f}−0297T_{f}²

The greatest process design challenge to produce SPRW tunable films is demonstrating an ability to produce films with reproducibility and predetermined SPRW values. Therefore, one of the most important results obtained from the DOE analysis is the empirical predictive equation produced by fitting Equation 2 to the measured SPRW values listed in Table A. In order to demonstrate the predictive capability of Equation 2 and the level of control of the process, a target SPRW for a gold film was chosen to be 640 nm. According to Equation 2, the appropriate deposition parameters to obtain this target SPRW are Tₛ=35° C., R_{d}=0.7 Å/s, and T_{f}=26 Å. The actual SPRW obtained from a gold film grown using these deposition parameters was 641 nm, a difference of only 1 nm. The predictive ability of Equation 2 and the control of the process were, therefore, demonstrated to be excellent.

SERS Substrate Fabrication

SERS substrates are fabricated by coating a substrate material with a film prescribed by the results obtained from the DOE substrate design process. The deposition process involves cleaning the substrate material, mounting the substrate materials into a vapor deposition apparatus such as a thermal evaporator, performing the deposition, performing post deposition processes such as annealing, and characterization of the SERS substrate.

Cleaning. Regardless of the substrate material chosen upon which to deposit the SERS amplifying film, the surfaces of the materials must be free of contaminants to ensure uniform deposition and adequate adhesion of the SERS film. Cleaning typically involves soaking or sonicating the substrate material in a series of cleaning solutions. In one embodiment of the cleaning procedure, glass substrate materials are sonicated for 10 minutes in order in each of the following solutions, dilute detergent in distilled water, distilled water, and acetone with drying under flowing nitrogen between each sonication. Many other cleaning solutions (such as aqua regia, various organic solvents, acids, bases, etc.) and procedures (such as heated sonication, irradiation, and soaking in caustic media, etc.) can be envisioned by one skilled in the art depending upon the substrate material and the condition of the material's surface.

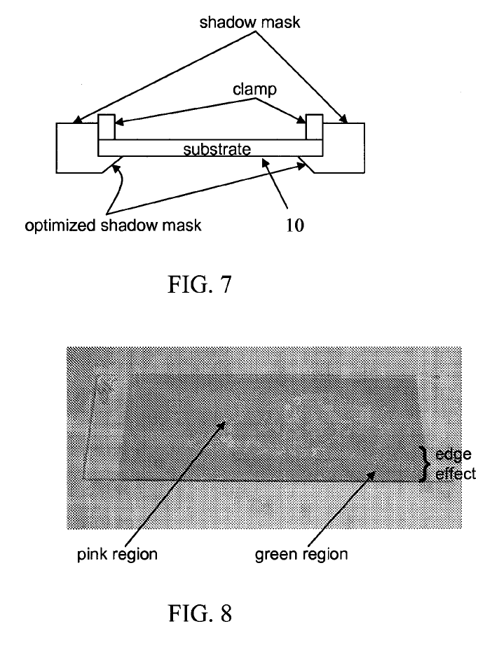

Mounting. The cleaned substrate materials are next mounted in an apparatus designed to control deposition parameters sufficiently to follow the prescribed by the design DOE. The presently disclosed and claimed invention includes a mounting method to ensure uniform deposition and maximize the useful area of a substrate by prearranging a perimeter shadow mask onto the surface of the substrate during deposition. The mask will minimize edge effects that result in non-uniform film properties that occur in vapor deposition in the absence of a perimeter mask. Such a mask, similar to that illustrated in FIG. 7, would ensure uniform deposition conditions (such as vapor flux, temperature, exposure angle, etc.) over the entire exposed area of the substrate to produce a uniform film over a large area.

FIG. 8 illustrates the non-uniformity of film properties that results from edge effects. The substrate is a 1 inch by 3 inch glass microscope slide coated with a gold island film that was clamped in place on both ends. The end clamps also served as shadow masks. No constraints or masking was used along the long edge of the slide.

FIG. 8 shows that the film is blue-green in color near the edges of the film while it is pink in color near the center of the film. Clearly, this film is not uniform. The central region is pink in color due to larger island sizes and larger inter-island spacing. The outer regions are blue-green because the islands are smaller in diameter and spaced closer together. The primary causes of the non-uniform film are due to non-uniform local deposition conditions very near the substrate across the substrate surface. The film near the edges of either clamped end is pink nearly up to the clamp position, particularly on the left edge of the film. The blue-green film region at the clamped edges is quite narrow and could be eliminated with an optimized mask geometry. Along the long edges of the film where no mask was employed, the blue-green region of the film extends from the substrate edge to nearly a fourth of the width of the film. Clearly, where no shadow mask is used, significantly non-uniform films can be expected and that non-uniformity can extend into the area of the film a significant distance. The edge effects illustrated in FIG. 8 are even more significant (i.e. extend farther into the film area) when larger area films are deposited on larger area substrate materials. The edge effects are also worse for unmasked films when deposition cycle times are reduced in order to mass produce large area films.

For large area films, it is absolutely essential that the films are uniform to ensure a constant SERS enhancement factor for an analyte placed at any position on the film. For a SERS based sensor, therefore, extremely high uniformity of the film and maximal film coverage are critical. Both of these requirements necessitate the use of an optimized perimeter shadow mask. Variations in the island geometry and spacing produce variations in SERS signal strength. Such variations produce, therefore, non-quantifiable measurements. Quantitative measurements, traceable to reliable standards, are absolutely necessary for the films to be used in a SERS based sensor.

Incorporation of a perimeter shadow mask of high thermal mass and conductivity that is suitable for high vacuum service, such as stainless steel, uniform heating of the substrate during deposition is achieved by integrating the mask into the substrate heating design. Actively heating at the edge of the substrate ensures uniform temperature of the substrate during deposition and post deposition annealing processing by counteracting thermal energy losses due to convection, conduction, and emission. In order to be effective, optimal thermal contact between the mask and substrate must be achieved so the mask is attached to and in physical contact with the exposed surface of the substrate to ensure efficient thermal energy flow between the mask and the substrate.

A perimeter shadow mask enables the formation of registration marks onto the substrate that may subsequently be used to ensure optimal optical alignment and substrate positioning during use in an autonomous SERS sensor application or device.

Deposition. The presently disclosed and claimed invention also includes a method for the formation of the film onto the surface of the substrate material. The film formation must be controlled so that the deposition parameters called for from the design DOE are maintained within acceptable tolerances. In one embodiment of the presently disclosed and claimed invention, the design DOE calls for precise control of deposition rate, substrate temperature, and SERS film thickness to constant values in a thermal evaporator. The deposition rate and film thickness are monitored using an oscillating crystal sensor and the substrate temperature is monitored using a thermocouple in contact with the substrate material or other suitable device such as an infrared radiation thermometer.

The deposition apparatus may be a thermal evaporator. In this case, metal vapor is formed in a vacuum chamber by heating a refractory metal, such as tungsten, vessel containing the metal to be deposited such as gold. Electrical current is passed through the boat, causing the boat to heat to high temperatures by resistive heating. Deposition parameters may be held constant or varied in a controlled manner during deposition. When the metal in the boat reaches a high enough temperature, the metal emits vapor consisting of the metal in the gas phase. If the vapor is allowed to contact a substrate, held at a much lower temperature, the vapor condenses on the substrate surface, allowing the accumulation of a film of the metal on the substrate surface. Numerous other methods for vapor depositing metal films are commercially available, such as laser ablation, electron beam evaporation, plasma assisted chemical vapor deposition, etc. and could be used in another embodiment of the presently disclosed and claimed invention.

Measurement Method. The presently disclosed and claimed invention further includes a method for optimal production of surface enhanced Raman spectra from biological materials. This invention incorporates the counterintuitive process of avoiding tuning the local surface plasmon resonance wavelength to between the laser and Raman shifted wavelengths since doing so produces deleterious effects for biological samples. Tuning the surface plasmon to between the laser and Raman shifted wavelengths to produce the maximum electric field adjacent to the outer surface of the substrate acts to denature biological material and results in the observation of enormous Raman signals due to carbon. These carbon signals result from the denaturation process. The electric fields associated with optimal surface plasmon resonance, therefore, are not desired for biological samples. In fact, for biological and other fragile materials, there does not exist a “desired” wavelength for the local surface plasmon resonance.

The presently disclosed and claimed invention includes a method to tune the surface plasmon resonance to any of a range of wavelengths significantly longer than that conventionally considered “optimal.” In other words, a suitable substrate for biological samples is one where the local surface plasmon resonance is tuned to any number of wavelengths that are longer than the Raman shifted wavelengths. So the generally accepted prior art “rule” for optimal tuning that prescribes to place the local surface plasmon resonance between the laser and Raman scattered wavelengths does not universally apply to biological materials.

Apparatus. Another embodiment of the presently disclosed and claimed invention uses a high volume air sampling system. This system is designed to collect and concentrate a measurable amount of analyte in a liquid and deliver an aliquot of the solution onto a SERS substrate surface, preferably in less than one minute. In one embodiment of the presently disclosed and claimed invention, the air sampling system permits the sampling of an air steam from a heating, ventilation, and air conditioning (HVAC) duct, and subsequent collection of aspirated particles. The air sampling system may include the installation of an in-line fluorescence sensor in the sampling conduit to permit detection of the presence of biological species and possible automated triggering of liquid sample transfer to a detection system. The system may be optimized with respect to the response time of air sampler by minimizing the time from initial introduction of sample to the registration of a detection response. The system may be further optimized with respect to minimizing the time necessary for concentration of analytes in the liquid phase which in effect minimizes the overall sampling collection time.

The present invention may incorporate a liquid handling system consisting of computer-controlled valves, a peristaltic pump, and a syringe/dispensing apparatus that may be configured to deliver highly-reproducible aliquots of extracted liquid phase onto the SERS substrate. In addition, the system may incorporate compact micro-positioning hardware that is able to facilitate precise movement of the sample dispenser and substrate turntable to optimize sample positioning with respect to the incident laser beam during sample deposition, evaporation, and SERS measurement processes. The air sampling and liquid delivery components may, in an alternate embodiment, be integrated to perform fully automated under computer control using process software that will allow autonomous operation of the SERS based sensor. Particularly, control of micro-positioning hardware and timing of individual actions may be achieved that include the duration of air sampling prior to liquid sample transfer, and the deposition of the sample droplets.

Self testing, optimization and calibration may be incorporated into the sensor to ensure accurate and reproducible measurements over long periods of time. Predeposited calibration samples may be place onto the surface of the SERS surface which may be periodically measured to achieve this elaborate self test. The system can be programmed to report its condition or adjust itself by taking corrective action such as undergoing an automated realignment process. Corrective action may be taken to maintain optimal performance with respect to sample reproducibility and execution within the timeframe allowable within the prescribed collection and measurement cycle. Contingent upon successful self testing of the entire sensor system, the operation of each individual component may be optimized to achieve maximum time efficiency, and sampling repeatability.

Various commercial designs for wetted-wall cyclone air sampling systems may be used in the SERS based sensor to optimize the collection efficiency, ease of operation, and compatibility with the specific requirements of the intended application.

The SERS substrates may be further enhanced by optimizing the process for fabrication of SERS substrates for the detection of specific analytes. Such optimization may include modification of the SERS film itself, modification of the composition, shape, and function of the substrate material supporting the SERS film. Optimization of the SERS substrate material function and other sensor functions may include turntable rotation speed and pause duration, solvent evaporation processing, heating and SERS laser powers, optical alignment, and spectrometer operation.

The software used for spectral analysis and analyte identification may be optimized by providing a model of the SERS sensor system that will enable the prediction of performance and perform post-measurement analysis on data generated by the SERS detector to identify and quantify the concentration of analytes very rapidly. Further optimization of the system software may include the incorporation of an analyte fingerprint algorithm to statistically match the measured SERS spectrum to the a spectrum in an analyte database. Also, clustering algorithms can be implemented, such as the well-tested Ward's algorithm.

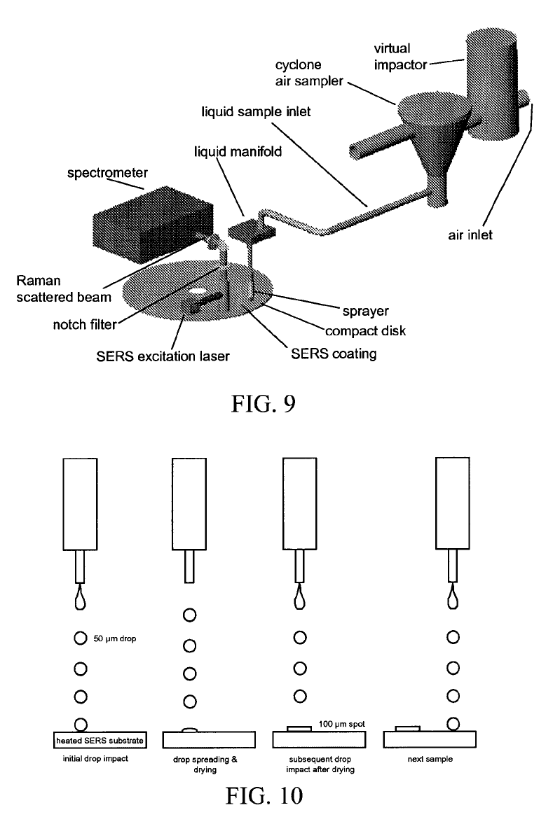

A schematic representation of one embodiment of the apparatus of the presently disclosed and claimed invention is shown in FIGS. 9 and 10. Briefly, airborne material is captured in a liquid to form a sample solution that is representative of the air concentration. An aliquot of this solution is applied to the surface of a turntable coated with a SERS film produced according to the methods disclosed herein. The turntable is then rotated to translate the sample to the measurement beam for detection and identification of the sample. This controlled application of the liquid sample concentrates the analyte to a small spot suitable for SERS measurement.

A novel aspect of the sensor system concept is the concentration of microliter scale liquid sample volumes onto extremely small (≦100 μm) spots on the SERS substrate prior to detection. Ink-jet technology is used to dispense sub nanoliter droplets onto the SERS substrate. For example, The individual droplets, nominally 50 μm in diameter, will wet out to nominally 100 μm spots on the SERS substrate. The combination of very high surface area to volume of the small droplets, plus the heating of the substrate, causes the droplets to evaporate in a fraction second. Using the inherent digital control of the ink-jet processes, subsequent droplets are applied after most of the previous drop has evaporated. Extending this process to hundreds or thousands of drops, the nonvolatile solids in the microliter scale liquid sample volume are concentrated onto a roughly 100 μm spot.

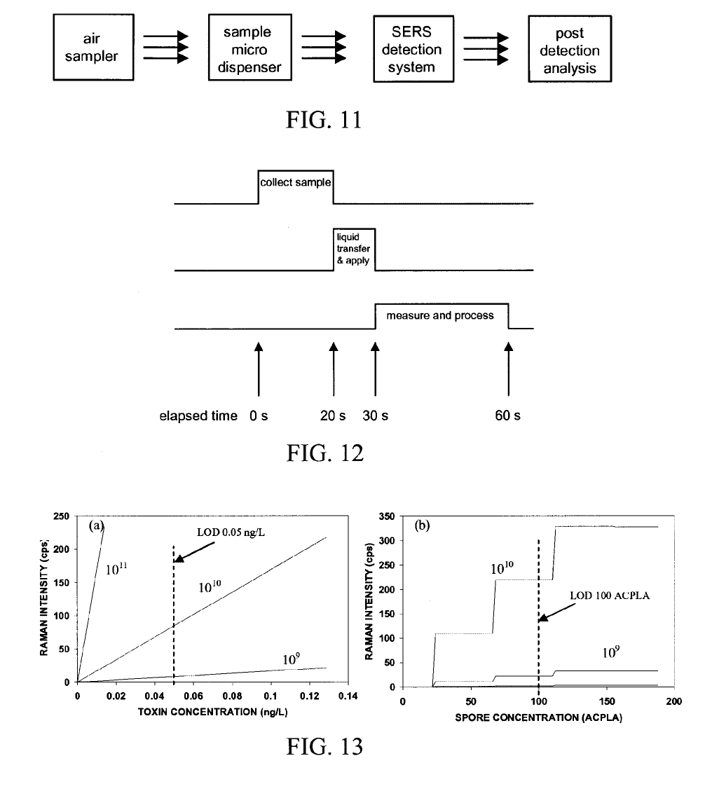

Below, a performance model for the present invention is described and the function is quantified for each of the subsystems in the design: air sampler, sample applicator, SERS detection system, and post detection analysis. A block diagram of these subsystems is shown in FIG. 11 and a timing diagram for the complete detection cycle is shown in FIG. 12.

Sample “clean-up” can be achieved during fluidic transfer between a wetted-wall cyclone sampler and the SERS module by a sequential series of rapid, on-line processes that may include separation of particles by size exclusion, selective partitioning of particles between aqueous and non-aqueous liquid phases, and mechanical agitation (sonic). Finally, a computer-controlled syringe dispenser can be used to inject a microliter volume of water into the liquid sample line, upstream from the deposition capillary, to displace an equal volume of “cleaned-up” liquid sample into the inkjet dispenser, or alternatively, a dispensing capillary. Provisions are to be made for automated purge/flushing of the sample transfer line following sample deposition. Following detection, the contents of the liquid phase could be automatically transferred to an appropriate receptacle for archiving purposes.

In order to verify the performance and reliability of the detection system on a day-to-day basis, an automated quality assurance (QA) scheme may be implemented. One such QA scheme requires the detector to examine a pre-deposited sample or samples containing an appropriate reference analyte in a mixture including typical background and particulate interferents. The objective is to confirm that the detection signal-to-noise ratio meets minimum specifications and that absolute identification can be achieved under challenging conditions. Pending the outcome of the QA procedure, the system can proceed with autonomous monitoring, or necessary corrective measures can be taken including modem or wireless or any other manual, automated or semi-automated communication means to initiate remote diagnosis.

During routine operation of this embodiment of the present invention, 5-8 ml of liquid phase containing accumulated aerosols will reside in the wetted-wall cyclone sampler during SERS identification of the most recently deposited sample. In the event of a positive identification of an analyte such as a biological pathogen, this volume, or some representative portion thereof, will be readily available for automated transfer to an appropriate receptacle for archiving purposes. In such an instance, the liquid phase is likely to contain a sufficient amount of analyte to enable confirmatory and forensic analyses at a later date.

A high velocity virtual impactor is incorporated into the first stage of the air sampling system. For example, the MSP Corporation Model 340 HVVI high volume virtual impactor samples air at 1130 L/min with a cut point of 2.5 μm. The second stage of the air sampler may also incorporate a wetted-wall cyclone. The wetted-wall cyclone sampler provides suction to extract sample stream air from the virtual impactor. Upon introduction of the extracted air stream into the wetted-wall cyclone, entrained particles collide with the thin liquid film coating the walls of the cyclone and are effectively removed from the sample air stream. A small volume (5-8 ml) of liquid continuously circulates through the cyclone chamber and accumulates particles from the sample air stream. Following a remote command, the liquid phase is transferred to the SERS detection module and the cyclone cup is recharged with fresh liquid.

Ink-jet printing technology can reproducibly dispense spheres of fluid with diameters of 15 to 100 μm (2 pl to 5 nl) at rates of 0-25,000 per second from a single drop-on-demand printhead. The deposition is non-contact, data-driven and can dispense a wide range of fluids. In a drop-on-demand ink-jet printer, the fluid is maintained at ambient pressure and a transducer is used to create a drop only when needed (see FIG. 9). The transducer creates a volumetric change in the fluid which creates pressure waves. The pressure waves travel to the orifice, are converted to fluid velocity, which results in a drop being ejected from the orifice.

The transducer in demand mode ink-jet systems can be either a structure that incorporates piezoelectric materials or a thin film resistor. In the later, a current is passed through this resistor, causing the temperature to rise rapidly. The ink in contact with it is vaporized, forming a vapor bubble over the resistor. This vapor bubble creates a volume displacement in the fluid in a similar manner as the electromechanical action of a piezoelectric transducer. Demand mode ink-jet printing systems produce droplets that are approximately equal in diameter to the orifice diameter of the droplet generator. Droplet generation rates for commercially available demand mode ink-jet systems are usually in the 4-12 kHz range. Droplets less than 20 μm are used in photographic quality printers, and drop diameters up to 120 μm have been demonstrated.

As a non-contact printing process, the volumetric accuracy of ink-jet dispensing is not affected by how the fluid wets a substrate, as is the case when positive displacement or pin transfer systems “touch off” the fluid onto the substrate during the dispensing event. In addition, the fluid source cannot be contaminated by the substrate, as is the potential during pin transfer touching. Finally, the ability to free-fly the droplets of fluid over a millimeter or more allows fluids to be dispensed into wells or other substrate features (e.g., features that are created to control wetting and spreading).

In general, piezoelectric demand mode technology can be more readily adapted to fluid microdispensing applications and it is easier to achieve lower drop velocities with piezoelectric demand mode. Piezoelectric demand mode does not create thermal stress on the fluid, which decreases the life of both the printhead and fluid. Piezoelectric demand mode does not depend on the thermal properties of the fluid to impart acoustic energy to the working fluid, adding an additional fluid property consideration to the problem.

As shown in FIGS. 9 and 10, the present detection system will interface the microdispenser to the wet walled cyclone air sampler to generate reproducible sample deposits on the SERS surface. The sample deposition parameters are optimized to produce the highest enhancement of the SERS signal. Laboratory results using micropipets have shown that a 5 μl drop yields acceptable deposits for SERS measurements, although the process is cumbersome. Therefore a 5 μl of sample can be deposited with the microdispenser using multiple (500-1000) drops.

Fundamental to the detection system, the signal (molecular signature amplitude) produced, S(e⁻) (in e⁻), for 1800 backscattering geometry and low f number optics used for both excitation laser focusing and Raman scatter collection: [94]

S(e⁻)=(P_{D}βN_{sc})(A_{D}Ω_{D}T^{col}Q)t, (3)

where P_{D} is the incident laser power density (in photons s⁻¹ cm⁻²), p is the differential Raman cross section (in cm² molecule⁻¹ sr⁻¹), N_{sc} is the number of scatterers per unit area (in molecule cm⁻²) on the SERS surface, A_{D} is the sample area monitored by the spectrometer (in cm²), Ω_{D} is the collection solid angle of the spectrometer at the sample (in steradians), T_{col} is the transmission of the collection optics (unitless), Q is the quantum efficiency of the detector (in e⁻ per photon), and t is the observation time (in seconds). In Equation 3, the first terms in parentheses, P_{D}, β, and N_{sc}, are related to the generation of Raman scattered photons and the remaining terms describe the detection of those photons.

Assuming an airborne concentration of Bacillus subtilis spores of 100 spores per liter of air, Cₐ=100 L⁻¹.

The wet walled cyclone sampler is capable of sampling air at a nominal rate of Aₛ=260 L/min with an efficiency for 1.0 μm diameter particles of 50%. Thus, the spore collection rate, R_{c}, for the cyclone air sampler is given in Equation 4 and is simply the product of the air concentration Cₐ, sampling rate Aₛ, and collection efficiency E_{c},

$${R}_{c} = {C}_{a} {A}_{s} {E}_{c} = ( \frac{100}{L} ) ( \frac{4.33 L}{s} ) 0.5 = 216.5 {s}^{- 1} . \qquad ( 4 )$$

The concentration of captured spores in the recirculating liquid, Cₛ, is given by Equation 5. The volume of recirculating liquid in the sampler is Vₛ=10 ml. Assuming a collection time of Tₛ=30 s, the concentration in the cyclone liquid is

$${C}_{s} = {R}_{c} {T}_{s} / {V}_{s} = ( \frac{216.5}{s} ) 30 s ( \frac{1}{0.01 L} ) = 649500 {L}^{- 1} . \qquad ( 5 )$$

The volume of recirculating liquid deposited onto the SERS surface is V_{d}=5.0 μl. Therefore, the number of spores collected from the recirculating liquid and delivered to the SERS surface in one drop, Nₛ, is

$${N}_{s} = {C}_{s} {V}_{d} {E}_{t} = ( \frac{649 , 500}{L} ) ( 5.0 \times {10}^{- 6} L ) 1.0 = 3.25 spores , \qquad ( 6 )$$

where Eₜ is the transfer efficiency of the 5.0 μl sample from the air sampler, through the transfer plumbing, to the SERS surface; a value of 1.0 is assumed.

Combining formulas 3-5, the number of spores, Nₛ, delivered to the SERS surface per sampling event is

Nₛ=CₐAₛE_{c}TₛEₜV_{d}/Vₛ, (7)

where all terms are defined above.

The shape of a Bacillus subtilis spore may be approximated to be a prolate spheroid with a minor axis of 0.75 μm and a major axis of 1.25 μm.[95] The cross sectional area of a single spore, therefore, is A′ₛₚ=π(r₁r₂)=7.4×10⁻⁹ cm². The collected spores, if close packed and a fill factor of F_{f}=80%, would occupy about Aₛₚ=NₛA′ₛₚ/F_{f}=3(7.4×10⁻⁹ cm²)/0.8=2.8×10⁻⁸ cm², nearly filling the 3.14×10⁻⁸ cm² excitation laser beam.

Here, it is assumed that the 3 spores dropped and evaporated onto the SERS surface are close-packed under the Raman laser beam. The 3 spores combine to an area of 2.2×10⁻⁸ cm². Since the laser beam area is 3.1×10⁻⁸ cm², perfectly placed spores will be fully illuminated by the laser.

The intensity of stokes shifted Raman scattered radiation, I_{R}, in all directions is [94]

I_{R}=P_{D}βN_{sc}, (8)

where P_{D} is the incident laser power density (in photons s⁻¹ cm⁻²) at the sample, β is the differential Raman cross section (in cm² molecule⁻¹ sr⁻¹), and N_{sc} is the number of scatterers per unit area (in molecules cm⁻²). The incident laser power, Pₒ, for the system is 70 μW, and the energy of each photon at 632.8 nm is Eₚ=hc/λ, where h is Planck's constant (6.626×10⁻³⁴ j s), c is the speed of light (3.0×10⁸ m/s), and λ is the laser wavelength (632.8×10⁻⁹ m). It is assumed that the incident laser radiation will excite Raman scattering over 20 bands. Therefore, the power density available for any given band will be 5% of the overall incident power:

$${P}_{D} = \frac{0.05 {P}_{o}}{{A}_{L} {E}_{p}} \\ = \frac{0.05 ( 70 \times {10}^{- 6} J / s )}{( 3.14 \times {10}^{- 8} {cm}^{2} ) ( 3.14 \times {10}^{19} J / photon )} \\ = 3.5 \times {10}^{20} photons {s}^{- 1} {cm}^{- 2} . \qquad ( 9 )$$

The Bacillus subtilis spore surface is composed of about 27 proteins.[96] Since they are weak scatterers, a typical value for the Raman cross section, β, of amino acids is, β=10⁻³⁰ cm² sr⁻¹ molecule⁻¹. From above, the area occupied by Nₛ=3 spores is A″ₛₚ=NₛA′ₛₚ=3(7.4×10⁻⁹ cm²)=2.2×10⁻⁸ cm². Assuming the area of a single amino acid is Aₐₐ=200 Å2 (or 2.0×10⁻¹⁴ cm²), the number of amino acids contained in the area of the 3 spores is Nₐₐ=A″ₛₚ/Aₐₐ=2.2×10⁻⁸ cm²/2.0×10⁻¹⁴ cm²=1.1×10⁶. It is further assumed that 100% of the 1.1×10⁶ surface amino acids are in contact with the SERS surface. The laser beam diameter A_{L} at the surface is used to calculate surface density of scatterers N_{sc}, thus

$${N}_{sc} = \frac{{N}_{aa}}{{A}_{L}} = \frac{1.1 \times {10}^{6}}{3.14 \times {10}^{- 8} {cm}^{2}} = 3.5 \times {10}^{13} molecule {cm}^{- 2} , \qquad ( 10 )$$

Combining results from Equations 9 and 10 and the value for β into Equation 8 yields

$${I}_{R} = {P}_{D} β {N}_{sc} \\ = ( \frac{3.5 \times {10}^{20} photons}{s {cm}^{2}} ) ( \frac{{10}^{- 30} {cm}^{2}}{sr molecule} ) ( \frac{3.5 \times {10}^{13} molecule}{{cm}^{2}} ) \\ = \frac{12 , 250 photons}{s sr {cm}^{2}} \qquad ( 11 )$$

Recalling from Equation 3 that S(e⁻)=I_{R}(A_{D}Ω_{D}T_{col}Q)t, the remaining terms related to the collection of Raman scattered light are evaluated, where A_{D}=3.1×10⁻⁸ cm², Ω_{D}=0.4 sr, T_{col}=50%, Q=80%:[94]

$$S ( {e}^{- } ) = \frac{12 , 250 photons}{s sr {cm}^{2}} ( \begin{matrix}3.1 \times \\ {10}^{- 8} {cm}^{2}\end{matrix} ) ( 0.4 sr ) ( 0.5 ) ( \frac{0.8 {e}^{-}}{photon} ) t \\ = \frac{6.1 \times {10}^{- 5} {e}^{-}}{s} t . \qquad ( 12 )$$

The signal to noise ratio is calculated as follows: [94]

$$SNR = \frac{{β}_{sc} {N}_{sc}}{{( {β}_{sc} {N}_{sc} + {β}_{B} {D}_{B} )}^{1 / 2}} {( {P}_{D} {A}_{D} Ω {T}_{coll} Qt )}^{1 / 2} , \qquad ( 13 )$$

where β_{sc}N_{sc} is the cross section density product for the signal and β_{B}N_{B} is the cross section density product for the detector background. β_{B}N_{B} includes contributions to the detector background signal from all sources such as shot noise, Johnson noise, dark count, flicker noise, and readout noise. For state-of-the-art CCD detectors, β_{B}N_{B} is roughly 1 e⁻ per second.

FIG. 13 shows Raman signals calculated for various airborne spore and toxin concentrations using performance values typical for a commercial cyclone wet walled sampler and a well designed Raman spectrometer. These results show that if a SERS enhancement factor of 1010 or greater is achieved, the system will have sufficient sensitivity to meet and exceed limits of detection requirements for bacteria and toxins of 100 spores per liter of air and 0.05 ng per liter of air, respectively. The results also show that a 10¹⁰ SERS enhancement factor produces a signal strong enough to allow for the detection cycle time of 1 minute or less to be achieved for both spores and toxins.

The false alarm rate for the system can be estimated using the well known threshold effect, a statistical analysis method developed in the communications industry for determining the error rate of digital signals.[97] The analogy of this effect to this analysis is straightforward, since it is desirable to establish the statistical significance of the detector producing a signal above or below a predetermined threshold (set to the threat level). Thus, determining a negative alarm condition (signal below threat level) or positive alarm condition (signal above threat level) is identical for binary digital signals representing a zero (below threshold) or a one (above threshold) respectively.

For signals containing Gaussian distributed noise, the probability of error in above or below threshold signals is:

$${P}_{e} = \frac{1}{2} [ 1 - erf ( \frac{A}{2 \sqrt{2} σ} ) ] , where erf ( x ) = \frac{2}{\sqrt{π}} {\int }_{0}^{x} {e}^{- {y}^{2}} d y \qquad ( 14 )$$

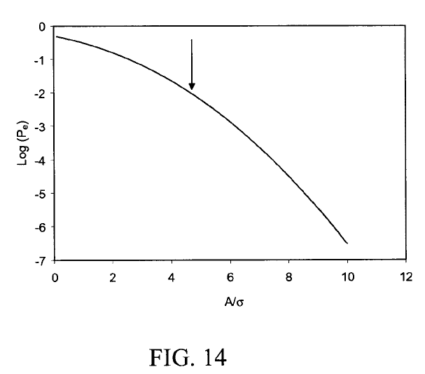

and where Pₑ is the probability of error, A is the maximum signal amplitude, σ is the signal standard deviation, and erf is the error function. It is assumed in Equation 14 that the threshold is set to A/2. For a prescribed false alarm rate of 10⁻², Equation 14 requires a signal to noise ratio, SNR=A/σ=4.8, as shown in FIG. 14. Clearly, the data in FIG. 1 exceeds this signal to noise ratio. The standard deviation term, σ, in Equation 14 contains contributions from all subsystems, including the air sampler, sample applicator, SERS detector, and post detection identification analyzer.

A complete propagation of error analysis of the subsystems can be performed to fully quantify contributions to the system uncertainty due to the subsystems with particular focus on the contribution due to uncertainty in analyte identification. In addition, a model can be derived to calculate the contribution to σ due to spectral clutter. Finally, a model to calculate the probability of detection in the form of a Receiver Operating Characteristic (ROC) curve can be developed. Similar ROC curves can also be generated using experimental data to verify the model.

Following air sampling and spectral acquisition, the rapid and reliable interpretation of the collected Raman signal is the final and perhaps the most crucial step in detecting a potential threat from an aerosol contagion. The interpretation of Raman spectra from complex media is challenging due to the high density of states from the immense number of individual oscillators in the sample, which coalesce into a spectrum composed of relatively few bands. A simple group frequency/structural class analysis is not applicable to such systems. In the presently disclosed and claimed invention, the interpretation of the Raman signal involves a three stage strategy following acquisition of the spectral data: (1) fingerprinting, (2) cluster analysis and, (3) threat evaluation.

To reduce the data set to a manageable size and in order to identify key aspects, the Raman spectra can be processed into characteristic fingerprints of equal or lower dimensionality, without loss of critical information. The primary fingerprint may be defined by the input spectral data, typically consisting of approximately 2000 data points over the spectral region 150 to 4000 cm⁻¹. The raw data can be normalized and the first- and second-derivative spectra are computed using a 9-pt technique, to allow the extraction of precise wavenumbers and integrated band intensities, minimizing concern for unavoidable baseline shifts. Secondary fingerprints, which are substantially more compact than the primary, can be derived from band analysis (frequency and intensity), region analysis (number of bands and total integrated intensity), local mode assignment (key vibration identification), statistical correlation analysis (PCA) and/or a combination of these.

A critical requirement for reliable correlation of analyte signal with known warfare agents is the development of a spectral library or database. Creation of a database, containing the fingerprints of analytes of interest is the first priority in working to develop the presence of analyte assessment algorithms.

TABLE B
Raman Spectral Wavenumber Region
Assignments.

| Region (cm⁻¹) | Assignment |
|---|---|
| 400-900 | True “Fingerprint Region” (variable, |
| | highly specific) |
| 900-1200 | Polysaccharide Region (cell surface |
| | markers) |
| 1200-1550 | Proteins, Fatty Acids and Phosphates |
| 1550-1800 | Mixed Region |
| 1800-3600 | Double, Triple Bonds and Hydrogen |
| | Stretches |

Cluster analysis is the automated categorization of data into algorithmically defined “clusters” based on similarity metrics. In the current context, it refers to the systematic comparison of the analyte fingerprint to entries in the database for the purpose of determining the presence of an analyte of interest. The analysis relies on the defined measures of closeness in comparing fingerprint signatures. Analysis is carried out on the fingerprints considering five spectral regions 400 to 900, 900 to 1200, 1200 to 1550, 1550 to 1800 and 1800 to 3600 cm⁻¹. These regions naturally suggest themselves since they correspond to scattering due to vibrational modes associated as indicated in Table B.

Similarity between fingerprints can be evaluated through a number of descriptors, including: Euclidian distance, maximum difference and projected length; along with an agglomerative clustering approach. Several clustering algorithms will be assessed, starting with the well-established Ward's algorithm, which seeks to minimize the total sum of squared deviations between analyte and database spectra.

The presently disclosed and claimed invention relates to a method to optimize deposition parameters to produce the highest SERS enhancement factor for specific Raman lines of a specific target molecule. This method involves producing a series of films according to a design of experiments (DOE) protocol whereby vapor deposition fabrication parameters (such as substrate temperature, deposition rate, film mass thickness, chamber pressure, and post deposition annealing) are set within predetermined parameter ranges and with specific combinations specified by the DOE. The SERS enhancement factor of each film is measured and a DOE statistical analysis is thereafter performed to quantify the effect of each deposition parameter on enhancement factor. This analysis quantifies the sensitivity and magnitude of the effect from which the optimum deposition parameters are obtained. An empirical predictive equation is produced from such a DOE statistical analysis that allows the deposition parameters to be set to produce a predetermined enhancement factor for a specific molecule.

In an alternative embodiment, the presently disclosed and claimed invention includes a method to produce a metal film having optimal surface enhancing properties for specific regions of the Raman spectrum. Often, a specific region of a Raman spectrum is of particular interest. It is useful, therefore, to enhance the SERS spectrum over a specific region of the spectrum. The spectral range (or width) over which the metal island films can produce a high SERS enhancing effect is limited, although, this range can be controlled to occur over a predetermined spectral region. This method involves producing a series of films according to a design of experiments (DOE) protocol whereby vapor deposition fabrication parameters (such as substrate temperature, deposition rate, film mass thickness, chamber pressure, and post deposition annealing) are set within predetermined parameter ranges and with specific combinations specified by the DOE. The spectral region and width of the SERS enhancement factor of each film is measured and a DOE statistical analysis is performed to quantify the effect of each deposition parameter on the spectral region and width of the SERS enhancement factor. The analysis quantified the sensitivity and magnitude of the effect from which the optimum deposition parameters are thereafter obtained. An empirical predictive equation is produced from such a DOE statistical analysis that allows the deposition parameters to be set to produce a film exhibiting maximized SERS enhancement over a predetermined spectral region of the SERS spectrum.

The presently disclosed and claimed invention further includes a method to deposit film with high SERS enhancement factor and increased film environmental durability. This method deposits a film with the SPRW to the red of laser line, then the film is heated in vacuum chamber immediately following deposition to blue shift the SPRW to optimum value. The procedure achieves a high SERS enhancement factor and increases film environmental durability due to annealing the metal islands and inducing them to form highly stable shapes. The post deposition heating causes a decrease in the metal island diameters along with a concurrent increase in the island heights. Both of these changes in island geometry produce a blue shift in the SPRW.

The presently disclosed and claimed invention also includes a method to treat substrate to adsorb molecules in gaps between gold islands on film. This method applies a coating to the substrate that exhibits a high affinity for a target analyte molecule prior to depositing gold. Following gold deposition, target molecules will thereafter have an affinity to adsorb in gaps between gold islands on film following application of the sample to the SERS film. Capturing the analyte molecules in the gaps between the gold islands maximizes the SERS enhancement factor for those molecules because it is believed that the electric field associated with the surface plasmon resonance is greatest maximum between the islands. Molecules captured such that they are engulfed by this maximum electric field will maximize the SERS spectrum produced.

In yet another aspect, the presently disclosed and claimed invention includes a method to deposit gold, silver, or other substance simultaneously or sequentially on a substrate. This method utilizes two or more vapor sources operating simultaneously, or in series, to produce islands comprising shell structures, amalgams, or mixtures onto the surface of various supporting substrate materials including, but not limited to glass, liquid crystal, ceramics, semiconductors, semimetals, polymers, fibers, composites, nanomaterials, and mixtures and/or combinations thereof. In one embodiment, silver islands are first deposited then followed with gold to produce gold coated silver islands. This method allows the optimization of metal island films to SERS systems using near infrared and longer wavelength laser excitation.

In yet another alternate embodiment, the presently disclosed and claimed invention includes a method to actively vary deposition parameters during deposition of a metal on a substrate. This method involves producing a series of films according to a design of experiments (DOE) protocol whereby vapor deposition fabrication parameters (such as substrate temperature, deposition rate, film mass thickness, chamber pressure, and post deposition annealing) are varied during deposition within predetermined parameter ranges and with specific combinations specified by the DOE. The SERS enhancement factor of each film is measured and a DOE statistical analysis is performed to quantify the effect of each deposition parameter and variation procedure on enhancement factor. This analysis quantifies the sensitivity and magnitude of the effects from which the optimum deposition parameters and variation procedures can be obtained. An empirical predictive equation is thereafter produced from the DOE statistical analysis that allows the deposition parameters to be set and varied to produce a predetermined enhancement factor for a specific molecule.

In an alternative embodiment, the presently disclosed and claimed invention includes methods to construct surface features on a substrate by manipulation of nanoscale particles such as colloids, nanorods, nanospheres, etc. As the field of nanotechnology matures, methods to place, position, and manipulate nanoparticles will evolve to where these methods will become economically feasible for incorporation into manufacturing processes. These methods include, but are not limited to, self assembly, molecular imprinting, dip pen lithography, sub nanometer lithography, and the like. These methods have in common the ability to control the geometry of matter on the nanometer scale, that is, less than 100 nm in dimension. In addition to metal island placement and separation control, these methods can incorporate features onto the surfaces of the islands on the same geometric scale as molecules, potentially the angstrom scale.

The presently disclosed and claimed invention further includes a method to produce films on a substrate with broad surface plasmon resonance spectra to simultaneously overlap excitation and Raman scattered wavelengths. This method involves producing a series of films according to a design of experiments (DOE) protocol whereby vapor deposition fabrication parameters (such as substrate temperature, deposition rate, film mass thickness, chamber pressure, and post deposition annealing) are varied during deposition within predetermined parameter ranges and with specific combinations specified by the DOE. The spectral dependence of the SERS enhancement factor of each film is measured and a DOE statistical analysis is performed that quantifies the effect of each deposition parameter and variation procedure on the spectral width over which the enhancing effect is optimized. This analysis quantifies the sensitivity and magnitude of the effects from which the optimum deposition parameters can be obtained. An empirical predictive equation is produced from the DOE statistical analysis that allows the deposition parameters to be set and varied to produce a predetermined spectral width for the enhancement effect for specific target molecules.

The presently disclosed and claimed invention includes a method to control evaporation of a liquid drop on the surface of a substrate to center analyte molecules under a SERS beam. This method optimizes the solvent evaporation process after a solution containing the analyte is dropped onto the SERS enhancing surface. After optimization, the solvent evaporation process transports analyte molecules or biomaterials to the center of the drop in close packed form such that the location of the molecules or biomaterials on the SERS enhancing surface is known. Since the location of the analyte molecules or biomaterials is known, focus of the SERS analyzing laser beam onto the analytes does not require imaging of the analytes to locate their position.

The presently disclosed and claimed invention also includes a method to produce uniform SERS active surfaces over large substrate areas such as compact disks. This method involves producing a series of films on large substrate materials (such as a compact disk) according to a design of experiments (DOE) protocol whereby vapor deposition fabrication parameters (such as substrate temperature, deposition rate, film mass thickness, chamber pressure, post deposition annealing, and substrate manipulation (e.g. planetary movement)) are set or varied during deposition within predetermined parameter ranges and with specific combinations specified by the DOE. The SERS enhancement factor of each film is measured at numerous locations and a DOE statistical analysis performed to quantify the effect of each deposition parameter and variation procedure on enhancement factor and reproducibility. The analysis quantifies the sensitivity and magnitude of the effects from which the optimum deposition parameters and variation procedures can be obtained. An empirical predictive equation is produced from the DOE statistical analysis that allows the deposition parameters to be set and varied to produce a predetermined enhancement factors and variability for specific molecules.

The presently disclosed and claimed invention further includes a method to grade the properties of metal island films using a moving mask during deposition. This method involves producing a series of films according to a design of experiments (DOE) protocol whereby vapor deposition fabrication parameters (such as substrate temperature, deposition rate, film mass thickness, chamber pressure, post deposition annealing, and mask movements) are set or varied during deposition within predetermined parameter ranges and with specific combinations specified by the DOE. The SERS enhancement factor of each film is measured for multiple analyte molecules and/or biomaterials and a DOE statistical analysis performed to quantify the effect of each deposition parameter, variation procedure, and mask movement on enhancement factor. The analysis quantifies the sensitivity and magnitude of the effects from which the optimum deposition parameters, variation procedures and mask movements can be obtained. An empirical predictive equation is produced from the DOE statistical analysis that allows the deposition parameters to be set and/or varied and the mask movement to be set or varied to produce a predetermined enhancement factor for a range of analyte molecules or bioimaterials.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

### REFERENCES

The following references, to the extent that they provide exemplary procedural or other details supplementary to those set forth herein, are specifically incorporated herein by reference in their entirety as though set forth herein in particular.
1. D. Naumann, in Infrared and Raman Spectroscopy of Biological Materials, edited by H-U. Gremlich and B. Yang (Dekker, New York, 2001), Ch. 9.
2. D. Naumann, in Infrared Spectroscopy: New Tool in Medicine, (Proc. SPIE, Vol. 3257, Bellingham, Wash., 1998, pp 245-257).
3. R. P. Van Duyne, K. L. Haller, and R. I. Altkorn, Chem. Phys. Lett, 126, 190 (1986).
4. B. Pettinger, K. Krischer, and G. Ertl, Chem. Phys. Lett. 151, 151 (1988).
5. P. Hildebrandt and M. Stockburger, J. Phys. Chem. 88, 5935 (1984).
6. S. Nie and S. R. Emory, Science 275, 1102 (1997).
7. K. Kneipp. Y. Wang, H. Kneipp, L. T. Perelman, I. Itzkan, R. R. Dasari, and M. S. Feld, Phys. Rev. Lett. 78, 1667 (1997).
8. A. M. Michaels, J. Jiang, and L. Brus, J. Phys. Chem. B, 104, 11965 (2000).
9. A. Weiss and G. Haran, J Phys. Chem. B, 105, 12348 (2001).
10. H. Xu, E. J. Bjerneld, M. Kall, and L. Borjesson, Phys. Rev. Lett, 83, 4357 (1999).
11. C. J. L. Constantino, T. Lemma, P. A. Antunes, and R. Aroca, Anal. Chem. 73, 3674 (2001).
12. C. J. L. Constantino, T. Lemma, P. A. Antunes, and R. Aroca, Spectrochim. Acta A, 58, 403 (2002).
13. A. Campion and P. Kambhampati, Chem. Soc. Rev. 27, 241 (1998).
14. M. Moskovits, Rev. Mod. Phys. 57, 783 (1985).
15. A. Otto, I. Mrozek, H. Grabhorn, and W. Akemann, J. Phys. Condens. Matter 4, 1143 (1992).
16. W. E. Doering and S. Nie, J. Phys. Chem. B, 106, 311 (2002).
17. N. Felidj, J. Aubard, G. Levi, J. R. Krenn, M. Salerno, G. Schider, B. Lamprecht, A. Leitner, and F. R. Aussenegg, Phys. Rev. B. 65, 075419 (2002).
18. R. Jin, Y. Cao, C. A. Mirkin, K. L. Kelly, G. C. Schatz, and J. G. Zheng, Science, 294, 1901 (2001).
19. P. Mulvaney, MRS Bull. 26, 1009 (2001).
20. J. Mock, M. Barbic, D. R. Smith, D. A. Schultz, and S. Schultz, J. Chem. Phys. 116, 6755 (2002).
21. A. K. Sarychev and V. M. Shalaev, in Optics of Nanostructured Materials, V. A. Markel and T. F. George, eds, (Wiley, New York, 2001); A. K. Sarychev and V. M. Shalaev, Phys. Rep. 335, 275 (2000).
22. A. Liebsch, Electronic Excitations at Metal Surfaces, (Plenum, New York, 1997).
23. S. Link and M. A. EI-Sayed, Int. Rev. Phys. Chem. 19, 409 (2000).
24. V. M. Shalaev, ed., Optical Properties of Nanostructured Random Media, (Springer, New York, 2002).
25. A. N. Shipway, E. Katz, and I. Willner, ChemPhysChem. 1, 18 (2000).
26. D. Bedeaux and J. Vlieger, Optical Properties of Surfaces, (Imperial College Press, London, 2002).
27. U. Kreibig and M. Vollmer, Optical Properties of Metal Clusters, (Springer, New York, 1995).
28. C. L. Haynes and R. P. Van Duyne, J. Phys. Chem. B. 105, 5599 (2001).
29. M. M. Alvarez, J. T. Khoury, T. G. Schaaff, M. N. Shafigullin, I. Vezmar, and R. L. Whetten, J. Phys. Chem. B. 101, 3706 (1997).
30. S. A. Maier, M. L. Brogersma, P. G. Kik, S. Meltzer, A. A. G. Requicha, and H. A. Atwater, Adv. Mater. 13, 1501 (2001).
31. R. P. Van Duyne, J. C. Hulteen, and D. A. Treichel, J. Chem. Phys. 99, 2101 (1993).
32. V. L. Schlegel and T. M. Cotton, Anal. Chem. 63, 241 (1991).
33. C. Douketis, T. L. Haslett, Z. Wang, M. Moskovits, and S. Iannotta, J. Chem. Phys. 113, 11315 (2000).
34. W. A. Weimer and M. J. Dyer, Appl. Phys. Lett. 79, 3164 (2001).
35. S-S. Chang, C-W. Shih, C-D. Chen, W-C. Lai, and C. R. C. Wang, Langmuir, 15, 701 (1999).
36. C.-D. Chen, Y.-T. Yeh, and C. R. C. Wang, J. Phys. Chem. Solids, 62, 1587 (2001).
37. J. Bosbach, D. Martin, F. Stietz, T. Wenzel, and F. Trager, Appl. Phys. Lett. 74, 2605 (1999).
38. D. A. Handley, in Colloidal Gold. Principles, Methods, and Applications, Vol. 1, M. A. Hayat, ed. (Academic Press, New York, 1989, p. 13).
39. N. R. Jana, L. Gearheart, and C. J. Murphy, Adv. Mater. 13, 1389 (2001).
40. N. R. Jana, L. Gearheart, and C. J. Murphy, J. Phys. Chem. B. 105, 4065 (2001).
41. C. H. Walker, J. V. St. John, and P. Wisian-Neilson, J. Am. Chem. Soc. 123, 3846 (2001).
42. A. C. Templeton, J. J. Pietron, R. W. Murray, and P. Mulvaney, J. Phys. Chem. B. 104, 564 (2000).
43. B. Kim, S. L. Tripp, and A. Wei, J. Am. Chem. Soc. 123, 7955 (2001).
44. R. M. Bright, M. D. Musick, and M. J. Natan, Langmuir, 14, 5701 (1998).
45. M. D. Malinsky, K. L. Kelly, G. C. Schatz, and R. P. Van Duyne, J. Am. Chem. Soc. 123, 1471 (2001).
46. I. Lyubinetsky, S. Mezhenny, W. J. Choyke, and J. T. Yates, Surf. Sci. 459, L451 (2000).
47. W. Schindler, D. Hofmann, and J. Kirchner, J. Appl. Phys. 87, 7007 (2000).
48. D. M. Kolb, R. Ullmann, and T. Will, Science, 275, 1097 (1997).
49. T. R. Jensen, G. C. Schatz, and R. P. Van Duyne, J. Phys. Chem. B. 103, 2394 (1999).
50. J. C. Hulteen, D. A. Treichel, M. T. Smith, M. L. Duval, T. R. Jensen, and R. P. Van Duyne, J. Phys. Chem. B. 103, 3854 (1999).
51. T. R. Jensen, M. L. Duval, K. L. Kelly, A. A. Lazarides, G. C. Schatz, and R. P. Van Duyne, J. Phys. Chem. B. 103, 9846 (1999).
52. M. D. Malinsky, K. L. Kelly, G. C. Schatz, and R. P. Van Duyne, J. Phys. Chem. B. 105, 2343 (2001).
53. X. Zhang, M. A. Young, O. Lyandres, and R. P. Van Duyne, J. Am. Chem. Soc., 127, 4484 (2005).
54. L. Eckertova, Physics of Thin Films, 2nd ed. Ch. 4 (Plenum Press, New York, 1986).
55. M. Levlin, A. Laakso, H. E.-M. Niemi, and P. Hautojarivi, Appl. Surf. Sci. 115, 31 (1997).
56. L. A. Lyon, C. D. Keating, A. P. Fox, B. E. Baker, L. He, S. R. Nicewarner, S. P. Mulvaney, and M. J. Natan, Anal. Chem. 70, 341R (1998).
57. A. Campion and P. Kambhampati, Chem. Soc. Rev. 27, 241 (1998).
58. K. Kneipp, H. Kneipp, I. Itzkan, R. R. Dasari, and M. Feld, Chem. Rev. 99, 2957 (1998).
59. S. P. Mulvaney and C. D. Keating, Anal. Chem, 72, 145R (2000).
60. Z. Q. Tian, B. Ren, and D. Y. Wu, J. Phys. Chem. B 106, 9463 (2002).
61. R. G. Freeman, K. C. Grabar, K. J. Allison, R. M. Bright, J. A. Davis, A. P. Guthrie, M. B. Hommer, M. A. Jackson, P. C. Smith, D. G. Walter, and M. J. Natan, Science, 276, 1629 (1995).
62. K. C. Grabar, R. G. Freeman, M. B. Hommer, and M. J. Natan, Anal. Chem. 67, 735 (1995).
63. M. D. Musick, C. D. Keating, L. A. Lyon, S. L. Botsko, D. J. Pena, W. D. Holliway, T. M. McEvoy, J. N. Richardson, and M. J. Natan, Chem. Mater. 12, 2869 (2000).
64. L. A. Lyon, D. J. Pena, and M. J. Natan, J. Phys. Chem. B. 103, 5826 (1999).
65. C. D. Keating, K. M. Kovaleski, and M. J. Natan, J. Phys. Chem. B 102, 9404 (1998).
66. C. D. Keating, K. M. Kovaleski, and M. J. Natan, J. Phys. Chem. B 102, 9414 (1998).
67. Y. C. Cao, R. J. Jin, and C. A. Mirkin, Science, 297, 1536 (2002).
68. C. L. Haynes, A. D. McFarland, M. T. Smith, J. C. Hulteen, and R. P. Van Duyne, J. Phys. Chem. B, 106, 1898 (2002).
69. T. R. Jensen, M. D. Malinsky, C. L. Haynes, and R. P. Van Duyne, J. Phys. Chem. B. 104, 10549 (2000).
70. S. Link and M. A. El-Sayed, J. Phys. Chem. B. 103, 4212 (1999).
71. L. G. Olson, Y. S. Lo, T. P. Beebe, and J. M. Harris, Anal. Chem. 73, 4268 (2001).
72. A. Wei, B. Kim, B. Sadtler, and S. L. Tripp, ChemPhysChem. 12, 743 (2001).
73. W. Gotschy, K. Vonmetz, A. Leitner, and F. R. Aussenegg, Appl. Phys. B. 63, 381 (1996).
74. P. C. Anderson and K. L. Rowlen, Appl. Spectrosc. 56, 124A (2002).
75. D. Graham, W. E. Smith, A. M. Linacre, C. H. Munro, N. D. Watson, and P. C. White, Anal. Chem. 69, 4703 (1997).
76. D. Graham, C. McLaughlin, G. McAnally, J. C. Jones, P. C. White, and W. E. Smith, Chem. Commun. 1187 (1998).
77. J. C. Jones, C. McLaughlin, D. Littlejohn, D. A. Sadler, D. Graham, and W. E. Smith, Anal. Chem. 71, 596 (1999).
78. R. Kier, D. Sadler, and W. E. Smith, Appl. Spectrosc. 56, 551 (2002).
79. C. McLaughlin, D. Graham, and W. E. Smith, J. Phys. Chem, 106, 5408 (2002).
80. C. Viets and W. Hill, J. Phys. Chem. B. 105, 6330 (2001).
81. D. J. Walls and P. W. Bohn, J. Phys. Chem. 93, 2976 (1989).
82. W. B. Lacy, J. M. Williams, L. A. Wenzler, T. P. Beebe, and J. M. Harris, Anal. Chem. 68, 1003 (1996).
83. Q. Ye, J. Fang, and L. Sun, J. Phys. Chem. B 101, 8221 (1997).
84. G. Compagnini, C. Galati, and S. Pignataro, Phys. Chem. Chem. Phys. 1, 2351 (1999).
85. A. Kudelski and B. Pettinger, Chem. Phys. Lett. 321, 356 (2000).
86. D. Buchel, C. Mihalcea, T. Fukaya, N. Atoda, J. Tominaga, T. Kikukawa, and H. Fuji, Appl. Phys. Lett. 79, 620 (2001).
87. R. J. Walsh and G. Chumanov, Appl. Spectrosc. 55, 1695 (2001).
88. A. Otto, J. Raman. Spectrosc. 33, 593 (2002).
89. P. J. Moyer, J. Schmidt, L. M. Eng, and A. J. Meixner, J. Am. Chem. Soc. 122, 5409 (2000).
90. J. T. Krug II, G. D. Wang, S. R. Emory, and S. Nie, J. Am. Chem. Soc. 121, 9208 (1999).
91. K. Kneipp, Y. Wang, H. Kneipp, I. Itzkan, R. R. Dasari, and M. S. Feld Phys. Rev. Lett. 76, 2444 (1996).
92. J. P. Luby, R. Clinton, and S. Kurtz, J. Clin. Virol., 12, 43 (1999).
93. S. R. Schmidt and R. G. Launsby, Understanding Industrial Designed Experiments, 4th ed. (Air Academy Press, Colorado Springs, Colo., 1994).
94. R. L. McCreery, “Raman Spectroscopy for Chemical Analysis,” Vol. 157 Chemical Analysis, J. D. Winefordner, ed. (Wiley, New York, 2000), Chapters 2, 6, and 13.
95. G. W. Faris, R. A. Copeland, K. Mortelmans, and B. V. Bronk, “Spectrally Resolved Absolute Fluorescence Cross Sections for Bacillus spores,” Appl. Opt. 36, 958 (1997).
96. E-M. Lai, N. D. Phadke, M. T. Kachman, R. Giorno, S. Vazquez, J. A. Vazquez, J. R. Maddock, and A. Driks, J. Bacteriol., 185, 1443 (2003).
97. M. Schwartz, Information Transmission, Modulation, and Noise, (McGraw-Hill, New York, 1980) ch. 5.

1. A method of producing a metallized substrate for surface enhanced Raman spectroscopy, the method comprising the steps of:
depositing at least one metal onto a substrate to provide the metallized substrate having a surface plasmon resonance; and
controlling one or more deposition parameters of the depositing step to tailor the surface plasmon resonance of the metallized substrate to a range of wavelengths longer than the Raman shifted wavelengths.

2. The method of claim 1 wherein the one or more deposition parameters include at least one of the parameters selected from the group consisting of temperature of the substrate during the depositing step, deposition rate, and amount of the metal deposited during the depositing step.

3. The method of claim 1 wherein the controlling step includes controlling each of the following deposition parameters, temperature of the substrate during the depositing step, deposition rate, and amount of the metal deposited during the depositing step.

4. The method of claim 1 wherein the metal is selected from the group consisting of silver, gold, and copper.

5. The method of claim 1 wherein the step of depositing at least one metal is accomplished using a thermal evaporator to perform the depositing step.

6. The method of claim 1 wherein the step of depositing at least one metal is accomplished by one of thermal evaporation, sputter deposition, electron-beam lithography, laser ablation, or chemical vapor deposition.

7. The method of claim 1 further comprising the step of determining at least one appropriate value for each of the one or more deposition parameters that result in the surface plasmon resonance of the metallized substrate to a range of wavelengths longer than the Raman shifted wavelengths.

8. The method of claim 7 further comprising the step of mounting the substrate into a perimeter shadow mask clamping the substrate along the substrate's perimeter establishing a thermal contact with the substrate along the perimeter edge.

9. The method of claim 8, further comprising actively heating the perimeter edges of the substrate via the perimeter shadow mask during the metal deposition, wherein heating the perimeter edges of the substrate minimizes formation of non-uniform metal film near the perimeter edges of the substrate.

10. A method of producing an enhancement surface for use in a surface enhanced Raman spectroscopy process, the method comprising the steps of:
determining an appropriate value for each of one or more deposition parameters to use in depositing metal onto a substrate to produce an enhancement whose surface plasmon resonance is tuned to a range of wavelengths longer than the Raman shifted wavelengths; and
depositing at least one metal onto a substrate in accordance with the determined value for each of one or more deposition parameters enhancement surface having surface plasmon resonance that is tuned to a range of wavelengths longer than the Raman shifted wavelengths.

11. The method of claim 10 wherein the one or more deposition parameters include at least one of the parameters selected from the group consisting of, temperature of the substrate during the depositing step, deposition rate, and amount of the metal deposited during the depositing step.

12. The method of claim 10 wherein the metal is selected from the group consisting of silver, gold, and copper.

13. The method of claim 10 wherein the step of depositing at least one metal is accomplished using a thermal evaporator to perform the depositing step.

14. The method of claim 10, wherein the step of depositing at least one metal is accomplished by one of thermal evaporation, sputter deposition, electron-beam lithography, laser ablation, or chemical vapor deposition.

15. The method of claim 10 wherein the excitation light source is a laser.

16. The method of claim 10 further comprising the step of mounting the substrate into a perimeter shadow mask clamping the substrate along the substrate's perimeter establishing a thermal contact with the substrate along the perimeter edge.

17. The method of claim 16, further comprising actively heating the perimeter edges of the substrate via the perimeter shadow mask during the metal deposition, wherein heating the perimeter edges of the substrate minimizes formation of non-uniform metal film near the perimeter edges of the substrate.
